(19) United States
(12) Patent Application Publication
(10) Pub. No.: US 2025/0380582 A1
(43) Pub. Date: Dec. 11, 2025

(54) DISPLAY PANEL AND DISPLAY DEVICE

(71) Applicants: Yungu (Gu’an) Technology Co., Ltd., Langfang (CN); Hefei Visionox Technology Co., Ltd., Hefei (CN)

(72) Inventors: Fa-Hsyang CHEN, Langfang (CN); Yinghai MA, Langfang (CN); Zidong GUO, Hefei (CN); Enqing GUO, Langfang (CN); Rubo XING, Langfang (CN); Junfeng LI, Langfang (CN)

(73) Assignees: Yungu (Gu’an) Technology Co., Ltd., Langfang (CN); Hefei Visionox Technology Co., Ltd., Hefei (CN)

(21) Appl. No.: 19/309,508

(22) Filed: Aug. 25, 2025

Related U.S. Application Data
(63) Continuation of application No. PCT/CN2023/106473, filed on Jul. 10, 2023.

(30) Foreign Application Priority Data
Feb. 27, 2023 (CN) 202310168062.2

(51) Int. Cl. H10K 59/124; H10K 102/00

(52) U.S. Cl. CPC H10K 59/124; H10K 2102/351

(57) ABSTRACT

Embodiments of the present application provide a display panel and a display device. The display panel includes: a substrate; an active layer disposed on the substrate; and a gate layer disposed on a side of the active layer facing away from the substrate, where the substrate includes an insulating dielectric film layer, a dielectric constant of the insulating dielectric film layer is less than a dielectric constant of the gate layer. The insulating dielectric film layer produces parasitic capacitance which affects a flow of carriers in the active layer. In the embodiments of the present application, a dielectric constant of the insulating dielectric film layer is less than a dielectric constant of the gate layer, so that the parasitic capacitance produced by the insulating dielectric film layer can be reduced, the influence of charges in the substrate on the carriers in the active layer can then be reduced.

### CROSS-REFERENCE TO RELATED APPLICATIONS

The present application is a continuation application of International Application No. PCT/CN2023/106473, filed on Jul. 10, 2023, which claims priority to Chinese Patent Application No. 202310168062.2, entitled “DISPLAY PANEL AND DISPLAY DEVICE” and filed on Feb. 27, 2023, both of which are incorporated herein by reference in their entireties.

### FIELD

The present application relates to the field of display equipment, and particularly to a display panel and a display device.

### BACKGROUND

An organic light-emitting diode (OLED) is an active light-emitting device. Compared with a conventional liquid crystal display (LCD) method, an OLED display technology does not require a backlight and has a self-luminescence characteristic. The OLED uses a thin film layer of an organic material and a glass substrate. When a current passes through the film layer of the organic material, the organic material emits light. Therefore, an OLED display panel can significantly save power, can be made lighter and thinner, withstands a wider range of temperature changes than an LCD display panel, and has a larger angle of view. The OLED display panel is expected to become the next generation of flat panel display technology after LCD, and is currently one of the flat panel display technologies that have attracted most attention.

The OLED display panel is mainly driven by a thin film transistor, the thin film transistor is disposed on the substrate, but there may be a charge in the substrate that affects the operation of the thin film transistor, which will result in image sticking of the display panel.

### SUMMARY

Embodiments of the present application provide a display panel and a display device, with the aim of improving the display effect of the display panel.

The embodiments of the present application provide a display panel, including: a substrate; an active layer disposed on the substrate; and a gate layer disposed on a side of the active layer facing away from the substrate, where the substrate includes an insulating dielectric film layer, a dielectric constant of the insulating dielectric film layer is less than a dielectric constant of the gate layer.

The embodiments of the present application further provide a display device, including a display panel according to any one of the above embodiments.

In the display panel provided in the embodiments of the present application, the display panel includes a substrate, an active layer and a gate layer, the gate layer is located between the active layer and an insulating dielectric film layer of the substrate, and the insulating dielectric film layer producing parasitic capacitance which affects a flow of carriers in the active layer. In the embodiments of the present application, the dielectric constant of the insulating dielectric film layer is less than the dielectric constant of the gate layer, so that the parasitic capacitance produced by the insulating dielectric film layer can be reduced, the influences of charges in the substrate on the carriers in the active layer can then be reduced, the influences of the charges in the substrate on the operation of a thin film transistor can be reduced, and the display effect of the display panel can thus be improved.

### BRIEF DESCRIPTION OF THE DRAWINGS

FIG. 1 is a structural schematic diagram of layers of a display panel according to an embodiment of the present application;

FIG. 2 is a structural schematic diagram of layers of a substrate of a display panel according to an embodiment of the present application;

FIG. 3 is a structural schematic diagram of layers of a substrate of a display panel according to another embodiment of the present application;

FIG. 4 is a partial structural schematic diagram of layers of a substrate of a display panel according to yet another embodiment of the present application; and

FIG. 5 is a graph of a just noticeable difference of a display panel of the present application as a function of dielectric constant.

### DETAILED DESCRIPTION OF THE EMBODIMENTS

In order to better understand the present application, a display panel and a display device according to the embodiments of the present application will be described in detail below with reference to FIGS. 1 to 5.

FIG. 1 is a structural schematic diagram of layers of a display panel according to an embodiment of the present application.

As shown in FIG. 1, the embodiments of the present application provides a display panel. The display panel includes a substrate 100, a gate layer 300, and an active layer 200, where the active layer 200 is provided on the substrate 100; the gate layer 300 is provided on a side of the active layer 200 facing away from the substrate 100; and the substrate 100 includes an insulating dielectric film layer 110 having a dielectric constant less than a dielectric constant of the gate layer 300.

In the display panel provided in the embodiments of the present application, the display panel includes the substrate 100, the active layer 200, and the gate layer 300, where the active layer 200 is located between the gate layer 300 and the insulating dielectric film layer 110 of the substrate 100, and the insulating dielectric film layer 110 produces parasitic capacitance which affects a flow of carriers in the active layer 200. In the embodiments of the present application, the dielectric constant of the insulating dielectric film layer 110 is less than the dielectric constant of the gate layer 300, so that the parasitic capacitance produced by the insulating dielectric film layer 110 can be reduced, the influences of charges in the substrate 100 on the carriers in the active layer 200 can then be reduced, the influences of the charges in the substrate 100 on the operation of a thin film transistor (TFT) can be reduced, and the display effect of the display panel can thus be improved.

The display panel further includes a drive device layer and a light-emitting device layer. The drive device layer is disposed on the substrate 100, and the active layer 200 and the gate layer 300 are disposed in the drive device layer. The drive device layer includes the thin film transistor (TFT), and the TFT includes a source electrode S, a drain electrode D, a gate electrode G, and a semiconductor portion B, where the semiconductor portion B is disposed in the active layer 200, and the gate electrode G is disposed in the gate layer 300. The light-emitting device layer is disposed on a side of the drive device layer facing away from the substrate 100, the light-emitting device layer includes light-emitting units, and the TFT is configured to drive the light-emitting units to emit light.

In the embodiments of the present application, the dielectric constant of the insulating dielectric film layer 110 is less than the dielectric constant of the gate layer 300, that is, the dielectric constant of the insulating dielectric film layer 110 is less than a dielectric constant of the gate electrode G, to reduce the parasitic capacitance produced by the insulating dielectric film layer 110, to reduce the influences of the charges in the substrate 100 on the operation of the TFT, to improve the properties of the TFT, to ameliorate the problems of driving hysteresis and image sticking of the display panel, and thus to improve the display effect of the display panel.

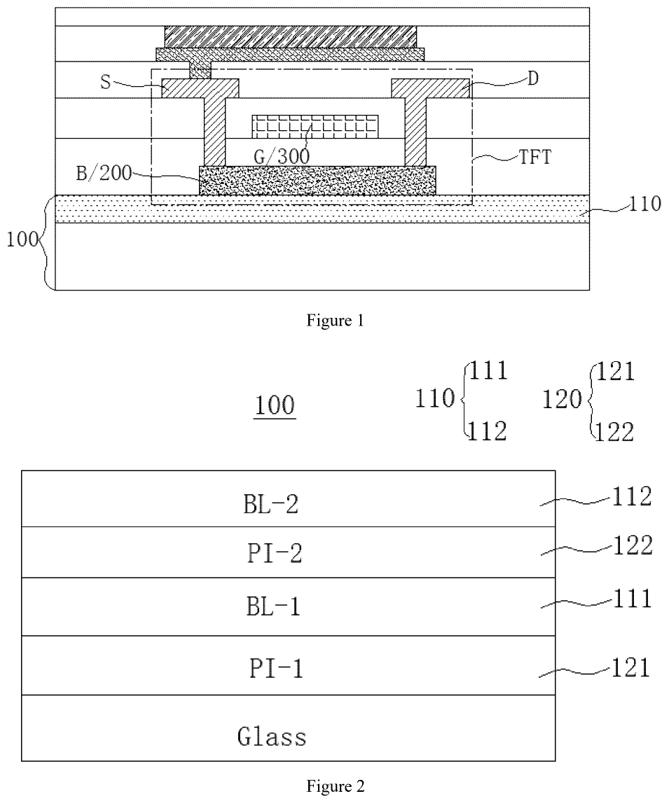

Referring to FIGS. 1 and 2 together, FIG. 2 is a structural schematic diagram of layers of the substrate 100 of a display panel according to an embodiment of the present application.

The substrate 100 may be configured in various ways, as shown in FIGS. 1 and 2, in one embodiment, the substrate 100 further includes a substrate layer 120, and the insulating dielectric film layer 110 may be provided on a side of the substrate layer 120 facing or away from the active layer 200. In one embodiment, at least one insulating dielectric film layer 110 is located between the substrate layer 120 and the active layer 200, and the dielectric constant of the insulating dielectric film layer 110 located between the substrate layer 120 and the active layer 200 is less than the dielectric constant of the gate layer 300.

In these embodiments, a distance between the insulating dielectric film layer 110 located between the substrate layer 120 and the active layer 200 and the active layer 200 is small, and the parasitic capacitance produced by the insulating dielectric film layer 110 has a large influence on the active layer 200. Setting the dielectric constant of the insulating dielectric film layer 110 between the substrate layer 120 and the active layer 200 to be less than the dielectric constant of the gate layer 300 can reduce the parasitic capacitance produced by the insulating dielectric film layer 110, the influences of the charges in the insulating dielectric film layer 110 on the operation of the TFT can thus be improved, and the display effect of the display panel can be improved.

In one embodiment, the substrate 100 may further include a glass base on which the insulating dielectric film layer 110 and the substrate layer 120 are both disposed.

In one embodiment, a material of the substrate layer 120 may include polyimide (PI). The substrate 100 may be configured in various ways, in one embodiment, the substrate 100 may be formed by stacking a plurality of substrate layers 120 and a plurality of insulating dielectric film layers 110.

In some embodiments, as shown in FIGS. 1 and 2, the substrate layer 120 includes a first substrate layer 121 and a second substrate layer 122; and the insulating dielectric film layer 110 includes a first insulating dielectric film layer 111 and a second insulating dielectric film layer 112, where the second insulating dielectric film layer 112 is located between the second substrate layer 122 and the active layer 200, the first insulating dielectric film layer 111 is located between the second substrate layer 122 and the first substrate layer 121, the first substrate layer 121 is located on a side of the second insulating dielectric film layer 112 facing away from the gate layer 300, and the dielectric constant of the second insulating dielectric film layer 112 is less than the dielectric constant of the gate layer 300.

In these embodiments, in a direction close to the active layer 200, the first substrate layer 121, the first insulating dielectric film layer 111, the second substrate layer 122 and the second insulating dielectric film layer 112 are sequentially stacked, and a distance between the second insulating dielectric film layer 112 and the gate layer 300 is minimum. Setting the dielectric constant of the second insulating dielectric film layer 112 to be less than the dielectric constant of the gate layer 300 can reduce the parasitic capacitance produced by the second insulating dielectric film layer 112, the influences of charges in the second insulating dielectric film layer 112 on the operation of the TFT can thus be improved, and the display effect of the display panel can be improved.

In some embodiments, the dielectric constants of the second insulating dielectric film layer 112 and the first insulating dielectric film layer 111 are both less than the dielectric constant of the gate layer 300.

In these embodiments, by decreasing the dielectric constants of both of the first insulating dielectric film layer 111 and the second insulating dielectric film layer 112, the parasitic capacitances produced by both the first insulating dielectric film layer 111 and the second insulating dielectric film layer 112 can be reduced, the influences of charges in both the first insulating dielectric film layer 111 and the second insulating dielectric film layer 112 on the operation of the TFT can thus be improved, and the display effect of the display panel can be improved.

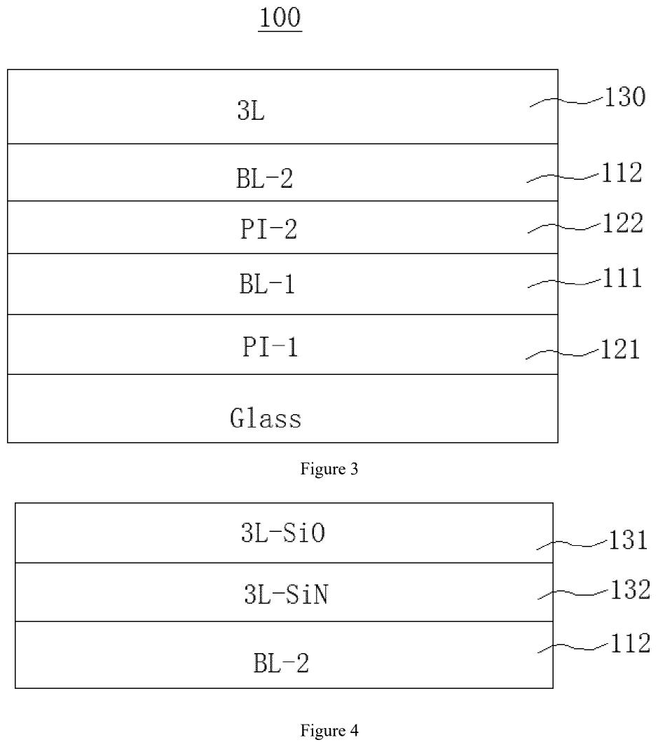

Referring to FIGS. 1 and 3 together, FIG. 3 is a structural schematic diagram of layers of a substrate 100 of a display panel according to another embodiment of the present application.

In some embodiments, as shown in FIGS. 1 and 3, an insulation layer 130 is provided between the second insulating dielectric film layer 112 and the active layer 200, and a thickness of the insulating dielectric film layer 110 is greater than a thickness of the insulation layer 130.

In these embodiments, since the dielectric constant of the second insulating dielectric film layer 112 is smaller, a thickness of the second insulating dielectric film layer 112 is set to be larger, and the thickness of the insulation layer 130 is set to be smaller, so that the requirement of insulation can be met, and the capacitance of the active layer 200 at a back channel can also be reduced.

A material of the insulation layer 130 may be provided in various ways, in one embodiment, the material of the insulation layer 130 includes at least one of silicon oxide and silicon nitride. The thickness of the insulation layer 130 can be set in various ways, and the thickness of the insulation layer 130 may range from 450 Å to 3000 Å.

Referring to FIGS. 1, 3 and 4 together, FIG. 4 is a partial structural schematic diagram of layers of a substrate 100 of a display panel according to yet another embodiment of the first embodiment of the present application.

In one embodiment, as shown in FIGS. 1, 3 and 4, the insulation layer 130 includes a first insulation layer 131 and a second insulation layer 132. In one embodiment, a material of the first insulation layer 131 includes silicon oxide, a material of the second insulation layer 132 includes silicon nitride, the first insulation layer 131 has a thickness of 2500 Å, the second insulation layer 132 has a thickness of 500 Å, and the first insulation layer 131 is located on a side of the second insulation layer 132 closing to the active layer 200. In one embodiment, the second insulating dielectric film layer 112 has a thickness of 6000 Å.

Thus, at the back channel of the active layer 200, a first parasitic capacitance C3 is produced at the first insulation layer 131, a second parasitic capacitance C2 is produced at the second insulation layer 132, and a third parasitic capacitance C1 is produced at the second insulating dielectric film layer 112. The produced total capacitance C of the active layer 200 at the back channel satisfies the following condition:

$$1 / C = 1 / C 1 + 1 / C 2 + 1 / C 3$$

When the thickness of the first insulation layer 131 is 2500 Å, the thickness of the second insulation layer 132 is 500 Å, and the thickness of the second insulating dielectric film layer 112 is 6000 Å, the total capacitance C can be about 71% of C1, about 0.38% of C2 and about 28% of C3 as a result. The influence of the second insulating dielectric film layer 112 on the total capacitance C of the active layer 200 at the back channel is the greatest, the dielectric constant of the second insulating dielectric film layer 112 is set to be smaller in the embodiments of the present application, the total capacitance C of the active layer 200 at the back channel can be effectively decreased, and the display effect of the display panel can be effectively improved.

In one embodiment, the dielectric constant of the insulation layer 130 is less than 4.4. The dielectric constant of the insulation layer 130 is small so that the parasitic capacitance at the insulation layer 130 can be decreased, and the display effect of the display panel can be further improved. In one embodiment, the dielectric constant of the insulation layer 130 may be 4.35, 4.3, 4.2, . . . , 3.5, etc.

In one embodiment, the dielectric constant of the insulating dielectric film layer 110 is less than or equal to 4.4, that is, the dielectric constants of the first insulating dielectric film layer 111 and the second insulating dielectric film layer 112 are less than or equal to 4.4. In one embodiment, the dielectric constant of at least one of the first insulating dielectric film layer 111 and the second insulating dielectric film layer 112 is 4.4, 4.3, 4.2, . . . , 3.1, 3.0, etc.

In one embodiment, the dielectric constant of the insulating dielectric film layer 110 is less than or equal to 4.25, that is, the dielectric constants of the first insulating dielectric film layer 111 and the second insulating dielectric film layer 112 are less than or equal to 4.25. In one embodiment, the dielectric constant of at least one of the first insulating dielectric film layer 111 and the second insulating dielectric film layer 112 is 4.25, 4.23, 4.2, . . . , 3.10, 3.05, 2.9, 2.7, 2.6, etc. In one embodiment, an gate insulation layer is provided between the gate layer 300 and the active layer 200, and the dielectric constant of the insulating dielectric film layer 110 is less than a dielectric constant of the gate insulation layer.

In these embodiments, the dielectric constant of the insulating dielectric film layer 110 is small enough to further improve the parasitic capacitance of the active layer 200 on the back channel side (i.e., a side of the active layer 200 away from the gate layer 300) and improve the display effect of the display panel.

A material of the insulating dielectric film layer 110 is provided in various ways, and the material of the insulating dielectric film layer 110 may include at least one of a silicon-based polymer material, a silicon oxide and an organic compound, as long as the dielectric constant of the insulating dielectric film layer 110 is less than the dielectric constant of the gate layer 300.

In one embodiment, the insulating dielectric film layer 110 may include SILK, a low dielectric-constant material developed by Dow Chemical. The low dielectric-constant material SiLK has a dielectric constant of 2.6, and can reduce the overall dielectric constant of the insulating dielectric film layer 110. In one embodiment, the insulating dielectric film layer 110 may include a porous SiLK material, that is, nanoscale pores are additionally formed in the low dielectric-constant material SiLK to obtain a porous SiLK material.

In one embodiment, the material of the insulating dielectric film layer 110 may include Fox, a low dielectric-constant material based on HSQ, which is developed by Dow Corning, and the low dielectric-constant material Fox has a dielectric constant of 2.98 and can reduce the overall dielectric constant of the insulating dielectric film layer 110.

In one embodiment, the material of the insulating dielectric film layer 110 may further include a silicon-based polymeric material (methylsil sesquioxane, MSQ), and by additionally forming nanoscale pores in the silicon-based polymeric material MSQ, the dielectric constant of the silicon-based polymer material MSQ can reach 2.2 to 2.5.

In one embodiment, the material of the insulating dielectric film layer 110 may further include HOSP, a low dielectric-constant material based on a mixture of an organic compound and a silicon oxide, which is launched by Honeywel.

In one embodiment, the material of the insulating dielectric film layer 110 may further include Black Diamond, a low dielectric-constant material based on chemically vapor deposited carbon doped silicon oxide, which is launched by Applied Materials.

In one embodiment, the material of the insulating dielectric film layer 110 may further include Coral, a low dielectric-constant material based on chemically vapor deposited carbon-doped silicon oxide, which is launched by Novellus. The low dielectric-constant material Coral has a dielectric constant of 2.7.

In one embodiment, the material of the insulating dielectric film layer 110 may further include Aurora, a low dielectric-constant material based on chemically vapor deposited carbon-doped silicon oxide, which is launched by ASM International, and the low dielectric-constant material Aurora has a dielectric constant of 2.7.

In one embodiment, carbon or fluorine may be doped in silicon oxide to obtain a low dielectric-constant material for preparing the insulating dielectric film layer 110. That is, the material of the insulating dielectric film layer 110 includes at least one of carbon-doped silicon oxide and fluorine-doped silicon oxide, or the material of the insulating dielectric film layer 110 is a mixture of an organic compound and a silicon oxide.

In some embodiments, the insulating dielectric film layer 110 has a temperature resistance greater than or equal to 400 degrees Celsius. The insulating dielectric film layer 110 has a high temperature resistance so that the service life and the yield of the display panel can be improved.

In some embodiments, the insulating dielectric film layer 110 has a film stress less than or equal to 100 MPa to reduce a film stress of the substrate 100, so that the service life and the yield of the display panel can be improved.

To further explain the beneficial effects of the present application, the present application further provides example 1, example 2, example 3, example 4 and comparative example 1. The substrates 100 in example 1, example 2, example 3, example 4 and comparative example 1 each include a first substrate layer 121, a first insulating dielectric film layer 111, a second substrate layer 122 and a second insulating dielectric film layer 112 as shown in FIG. 2. The difference between example 1, example 2, example 3, example 4 and comparative example 1 lies in that the first insulating dielectric film layer 111 and the second insulating dielectric film layer 112 have different dielectric constants.

K represents the dielectric constants of the first insulating dielectric film layers 111 and the second insulating dielectric film layers 112 in the examples, and JND (Just noticeable difference) represents a minimum noticeable difference of the display panel observed at 0s, this is, a minimum perceptible difference when the display panel is activated.

As shown in the table above, the dielectric constants of the insulating dielectric film layers 110 in example 1, example 2, example 3, example 4 and comparative example 1 increase sequentially, and the dielectric constant in comparative example 1 is greater than 4.4.

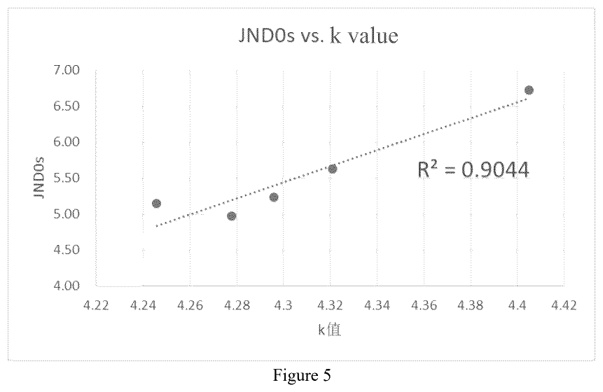

It can be seen from the above table and with respect to FIG. 5, excluding the influences of errors, as the dielectric constant of the insulating dielectric film layer 110 gradually increases, the minimum noticeable difference of the display panel observed when the display panel is activated (i.e., at 0s) gradually increases. Also, when the dielectric constant is greater than 4.4, the JND increases significantly.

Therefore, in the embodiments of the present application, by decreasing the dielectric constant of the insulating dielectric film layer 110, especially when the dielectric constant of the insulating dielectric film layer 110 is less than or equal to 4.4, the display effect of the display panel can be effectively improved.

An embodiment of the present application further provides a display device, including a display panel according to any one of the above embodiments. Since the display device according to the embodiment of the present application includes the display panel according to any one of the above-described embodiments, the display device according to the embodiment of the present application has the beneficial effects of the display panel according to any one of the above-described embodiments, which will not be repeated herein.

The display device in the embodiments of the present application includes, but is not limited to devices having a display function, such as a cell phone, a personal digital assistant (PDA), a tablet computer, an e-book, a television, an access control, a smart fixed-line telephone, or a control console.

What is claimed is:

1. A display panel, comprising:
a substrate;
an active layer disposed on the substrate; and
a gate layer disposed on a side of the active layer facing away from the substrate,
wherein the substrate comprises an insulating dielectric film layer, a dielectric constant of the insulating dielectric film layer being less than a dielectric constant of the gate layer.

2. The display panel according to claim 1, wherein the substrate further comprises a substrate layer, the insulating dielectric film layer is located between the substrate layer and the active layer, and the dielectric constant of the insulating dielectric film layer located between the substrate layer and the active layer is less than the dielectric constant of the gate layer.

3. The display panel according to claim 2, wherein
the substrate layer comprises a first substrate layer and a second substrate layer, and
the insulating dielectric film layer comprises a first insulating dielectric film layer and a second insulating dielectric film layer,
wherein the second insulating dielectric film layer is located between the second substrate layer and the active layer, the first insulating dielectric film layer is located between the second substrate layer and the first substrate layer, the first substrate layer is located on a side of the second insulating dielectric film layer facing away from the gate layer, and the dielectric constant of the second insulating dielectric film layer is less than the dielectric constant of the gate layer.

4. The display panel according to claim 3, wherein the dielectric constants of both of the second insulating dielectric film layer and the first insulating dielectric film layer are less than the dielectric constant of the gate layer.

5. The display panel according to claim 3, wherein an insulation layer is provided between the second insulating dielectric film layer and the active layer, and a thickness of the second insulating dielectric film layer is greater than a thickness of the insulation layer.

6. The display panel according to claim 5, wherein a material of the insulation layer comprises at least one of silicon oxide and silicon nitride.

7. The display panel according to claim 5, wherein the insulation layer comprises a first insulation layer and a second insulation layer.

8. The display panel according to claim 7, wherein a material of the first insulation layer comprises silicon oxide, and a material of the second insulation layer comprises silicon nitride.

9. The display panel according to claim 7, wherein the first insulation layer has a thickness of 2500 Å, and the second insulation layer has a thickness of 500 Å.

10. The display panel according to claim 7, wherein the first insulation layer is located on a side of the second insulation layer closing to the active layer.

11. The display panel according to claim 5, wherein the second insulating dielectric film layer has a thickness of 6000 Å.

12. The display panel according to claim 5, wherein a dielectric constant of the insulation layer is less than 4.4.

13. The display panel according to claim 1, wherein the dielectric constant of the insulating dielectric film layer is less than or equal to 4.4.

14. The display panel according to claim 8, wherein the dielectric constant of the insulating dielectric film layer is less than or equal to 4.25.

15. The display panel according to claim 1, wherein a material of the insulating dielectric film layer comprises at least one of a silicon-based polymer material, a silicon oxide and an organic compound.

16. The display panel according to claim 10, wherein the material of the insulating dielectric film layer comprises at least one of carbon-doped silicon oxide and fluorine-doped silicon oxide.

17. The display panel according to claim 10, wherein the material of the insulating dielectric film layer is a mixture of an organic compound and a silicon oxide.

18. The display panel according to claim 1, wherein the insulating dielectric film layer has a temperature resistance greater than or equal to 400 degrees Celsius.

19. The display panel according to claim 1, wherein the insulating dielectric film layer has a film stress less than or equal to 100 MPa.

20. A display device, comprising:
a display panel, comprising:
a substrate;
an active layer disposed on the substrate; and
a gate layer disposed on a side of the active layer facing away from the substrate, wherein the substrate comprises an insulating dielectric film layer, a dielectric constant of the insulating dielectric film layer being less than a dielectric constant of the gate layer.
